(19) United States
(12) Patent Application Publication
(10) Pub. No.: US 2026/0114219 A1
(43) Pub. Date: Apr. 23, 2026

(54) SUBSTRATE HEATING DEVICE AND SUBSTRATE PROCESSING DEVICE COMPRISING SAME

(71) Applicant: JUSUNG ENGINEERING CO., LTD., Gwangju-Si, Gyeonggi-Do (KR)

(72) Inventors: Min Jong KEUM, Gwangju-Si, Gyeonggi-Do (KR); Chul Joo HWANG, Gwangju-Si, Gyeonggi-Do (KR)

(21) Appl. No.: 18/859,945

(22) PCT Filed: Apr. 13, 2023
(86) PCT No.: PCT/KR2023/005032

§ 371 Date: Jun. 12, 2025

(30) Foreign Application Priority Data
Apr. 25, 2022 (KR) 10-2022-0050917

(51) Int. Cl. H10P 72/00; G03F 7/16; H05B 3/22

(52) U.S. Cl. CPC H10P 72/0434; G03F 7/168; H05B 3/22

(57) ABSTRACT

Provided are a substrate heating device and an apparatus for processing a substrate having the same, and more particularly, to a substrate heating device that heats a substrate and an apparatus for processing a substrate having the same. The substrate heating device includes a substrate support part configured to seat a substrate thereon and a plurality of heaters which is provided below the substrate support part and each of which includes a connection terminal provided on an end of each of the plurality of heaters and a heat generation body extending from the connection terminal in one direction. The plurality of heaters are disposed alternatively so that partial areas comprising the ends overlap each other in a direction crossing the one direction.

The present disclosure relates to a substrate heating device and apparatus for processing substrate having the same and more particularly, to a substrate heating device used to heat a substrate and apparatus for processing substrate having the same.

### BACKGROUND

In general, a semiconductor device or display device is manufactured by depositing various material on a substrate in a thin film shape and patterning the deposited thin film. For this, several stages of different processes such as a deposition process, an etching process, a cleaning process and a drying process are performed.

Here, the deposition process is performed to form a thin film having properties required as a semiconductor device or display device on the substrate. To form the thin film on the substrate in the deposition process, the substrate may be sufficiently heated in advance to perform the deposition process, thereby reducing a deposition time and improving deposition efficiency.

In the case of a large-area substrate, since a heating rate of the substrate is low, the substrate is preheated in a preheating chamber or a loadlock chamber before a main process. If a substrate that is not preheated is introduced into a process chamber for the main process, a process time taken to heat the substrate in the process chamber is additionally required.

In related art, to heat the substrate or preheat or heat the large-area substrate in the deposition process, the substrate is heated using a heating device in which linear heaters extending in one direction are disposed for a plurality of sections in the extension direction. However, in this case, a non-heat generation area in which a heating part is not disposed is inevitably generated between adjacent sections due to connection terminals provided on ends of linear heaters, and thus, there is a difficult to uniformly heat the substrate.

### RELATED ART DOCUMENT

### Patent Document

(Patent Document 1) KR 10-2012-0040124 A

### SUMMARY

### Technical Problem

The present disclosure provides a substrate heating device capable of minimizing a non-heat generation area and an apparatus for processing a substrate having the same.

### Technical Solution

In accordance with an exemplary embodiment, a substrate heating device includes: a substrate support part configured to seat a substrate thereon; and a plurality of heaters which is provided below the substrate support part and each of which includes a connection terminal provided on an end of each of the plurality of heaters and a heat generation body extending from the connection terminal in one direction, wherein the plurality of heaters are disposed alternatively so that partial areas comprising the ends overlap each other in another direction crossing the direction.

The plurality of heaters may include a first heater and a second heater, which are disposed alternatively, wherein the first heater and the second heater may be disposed so that the connection terminals do not overlap each other, and the heat generation bodies do not overlap each other.

The substrate heating device may further include: an electrode to which a power source is connected; and a cover having a through-hole and provided on the electrode, wherein the connection terminal may be electrically connected to the electrode through the through-hole.

The substrate heating device may further include a connection member passing through the through-hole to connect the connection terminal to the electrode.

The substrate heating device may further include a bolt inserted into the through-hole so that the connection member is coupled to the electrode.

The cover may be made of an insulating material.

The substrate heating device may further include a reflection plate provided below the plurality of heaters.

All of the plurality of heaters may be disposed on the reflection plate, and an edge of the reflection plate may be bent to surround the plurality of heaters.

In accordance with another exemplary embodiment, an apparatus for processing a substrate includes: a chamber configured to provide a process space; and any one of the above-described substrate heating devices installed in the process space.

### Advantageous Effects

According to the exemplary embodiment, the plurality of heaters may be disposed so that the partial areas of the connection terminals overlap each other to minimize the non-heat generation area on which the heat is not generated, thereby uniformly heating the substrate.

In addition, the insulating cover may be disposed between the connection terminal provided in each heater and the electrode for applying the power to the connection terminal to prevent the arc from being generated, and the heat released from the heater may be concentrated into the substrate through the reflection plate to improve the heating efficiency.

### BRIEF DESCRIPTION OF THE DRAWINGS

FIG. 1 is a view illustrating a state in which a plurality of heaters are arranged in accordance with an exemplary embodiment;

FIG. 2 is a view illustrating a state in which a connection terminal and an electrode are connected to each other in accordance with an exemplary embodiment;

FIG. 3 is a view illustrating a state in which a substrate heating device is installed in a process chamber in accordance with an exemplary embodiment; and

FIG. 4 is a view illustrating a state in which the substrate heating device is installed in a loadlock chamber in accordance with an exemplary embodiment.

### DETAILED DESCRIPTION OF EXEMPLARY EMBODIMENTS

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art. In the figures, the dimensions of layers and areas may be exaggerated for clarity of illustration. Like reference numerals refer to like elements throughout.

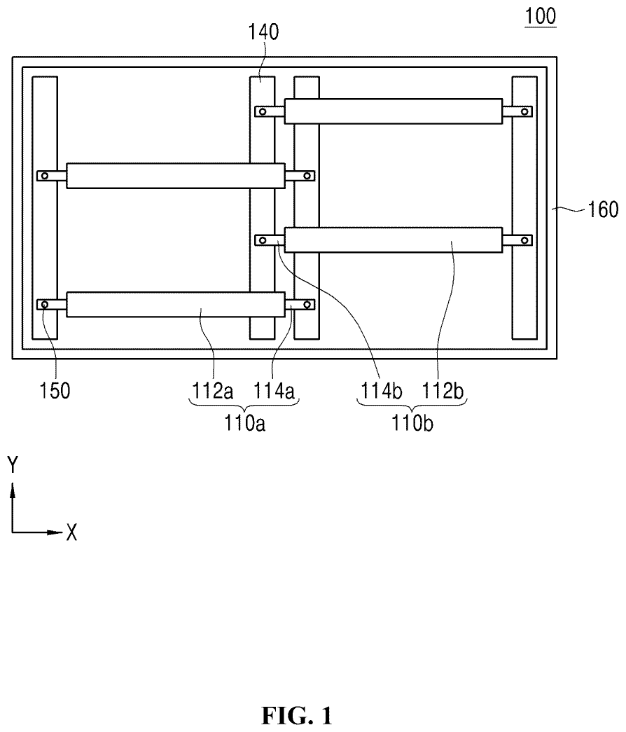

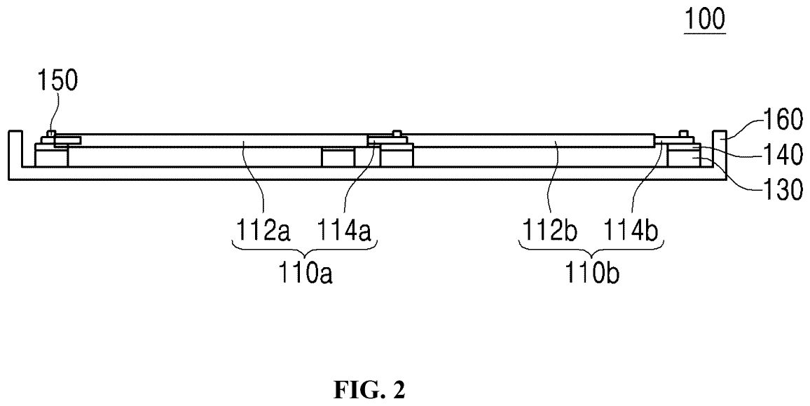

FIG. 1 is a view illustrating a state in which a plurality of heaters are arranged in accordance with an exemplary embodiment, and FIG. 2 is a view illustrating a state in which a connection terminal and an electrode are connected to each other in accordance with an exemplary embodiment.

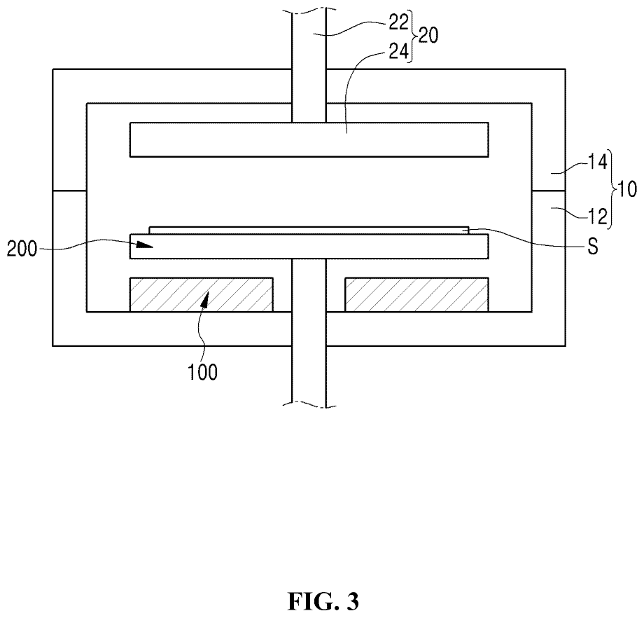

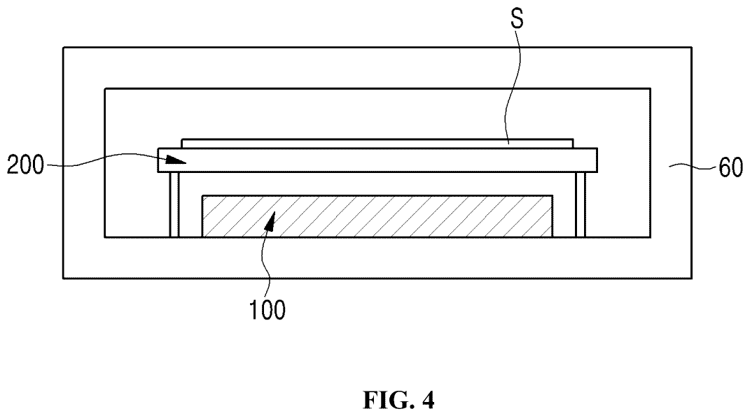

A substrate heating device in accordance with an exemplary embodiment includes a substrate support part 200 (see FIGS. 3 and 4) for seating a substrate and a substrate heating part 100 provided below the substrate support part to heat the substrate. Here, the substrate support part is configured to support the substrate and will be described with reference to FIGS. 3 and 4.

Referring to FIGS. 1 and 2, the substrate heating part 100 in accordance with an exemplary embodiment includes connection terminals 114a and 114b provided on ends thereof and a plurality of heaters 110a and 110b extending from the connection terminals 114a and 114b in one direction. The plurality of heaters 110a and 110b are alternatively disposed so that partial areas including the ends overlap each other in another direction crossing through one direction. In addition, the plurality of heaters 110a and 110b may be disposed so that the connection terminals 114a and 114b do not overlap the heat generation bodies 112a and 112b, respectively.

The plurality of heaters 110a and 110b may include a plurality of first heaters 110a extending in one direction and disposed alternately in the one direction and a plurality of second heaters 110b extending in one direction and disposed alternatively in the one direction. For example, the plurality of first heaters 110a may extend in an X-axis direction and disposed to be spaced apart from each other in a Y-axis direction perpendicular to the X-axis direction, and also, the plurality of second heaters 110b may extend in the X-axis direction and disposed to be spaced apart from each other in the Y-axis direction perpendicular to the X-axis direction.

Each of the plurality of first heaters 110a may include a first heat generation body 112a extending in one direction, i.e., the X-axis direction and a first connection terminal 114a provided on an end of the first heat generation body 112a. Here, the first connection terminal 114a may be provided on one end of the first heat generation body 112a, provided on the other end that is opposite to the one end, or provided on one end and the other end, i.e., both ends. Like the plurality of first heaters, each of the plurality of second heaters may include a second heat generation body 112b extending in one direction, i.e., the X-axis direction and a second connection terminal 114b provided on one end, the other end, or both ends of the second heat generation body 112b.

Each of the plurality of first heaters 110a and second heaters 110b may include a lamp heater extending in one direction. That is, each of the plurality of first heaters 110a and second heaters 110b, for example, each of the heat generation bodies 112a and 112b may include a transparent tube made of a material such as quartz or include a filament made of a material such as tungsten (W). That is, the plurality of first heaters 110a and second heaters 110b may be lamp heaters in which the connection terminals 114a and 114b connected to an external power source to heat the filaments are provided on ends of the heat generation bodies 112a and 112b including the transparent tube and the filament. Each of the lamp heaters may be provided by allowing the transparent tube to extend in one direction, i.e., in the form of a straight line. When the lamp heater extends in the form of the straight line, an area occupied by the lamp heater may be reduced compared to a case in which the lamp heater extends in a U shape. Thus, when the lamp heater is installed in the chamber, an unnecessary area due to the installation of the lamp heater may be minimized to minimize a process space of the chamber.

In the related art, to heat the substrate in the deposition process or to preheat or heat the large-area substrate in the deposition process, the substrate may be heated using, for example, a heating device in which the plurality of first heaters 110a extending in the X-axis direction and arranged in the Y-axis direction and the plurality of second heaters 110b extending in the X-axis direction and arranged in the Y-axis direction are disposed to be spaced apart from each other for each section in the X-axis direction. However, in this case, since no heat is generated in an area between the first heater 110a and the second heater 110b, a non-heat generation area on which the substrate is not heated is generated. In addition, even when the plurality of first heaters 110a and the plurality of second heaters 110b are disposed very close to each other, since the first connection terminal 114a provided on the end of the first heater 110a and the second connection terminal 114b provided on the end of the second heater 110b to face the first connection terminal do not release sufficient heat for heating the substrate, the non-heat generation area due to the connection terminals 114a and 114b facing each other may be inevitably generated, and thus, it may be difficult to uniformly heat the substrate.

Therefore, in the substrate heating part 100 in accordance with an exemplary embodiment, the plurality of heaters 110a and 110b extending in the one direction may be disposed alternately so that partial areas including the ends overlap each other in a direction crossing the one direction to minimize the non-heat generation area.

For example, as illustrated in FIG. 1, the plurality of first heaters 110a may extend in the X-axis direction and be spaced apart from each other in the Y-axis direction. In addition, the second heater 110b may be disposed at one side of the first heater 110a in the X-axis direction. Here, the plurality of second heaters 110b may also extend in the X-axis direction and be disposed to be spaced apart from each other in the Y-axis direction. Here, in the second heater 110b, the area extending between the plurality of first heaters 110a and including the connection terminal 114a provided at a right end of the first heater, i.e., at a right side of the first heater 110a and the area including the connection terminal 114b provided at a left end of the second heater 110b, i.e., provided at a left side of the second heater 110b are disposed to overlap each other in the Y-axis direction. Thus, the non-heat generation area in the X-axis direction, which is formed by the connection terminals 114a and 114b, may be minimized.

As illustrated in FIG. 1, the plurality of heaters 110a and 110b may be arranged so that the connection terminals 114a and 114b and the heat generation bodies 112a and 112b do not overlap each other. That is, the first connection terminal 114a of the first heater 110a may be disposed to overlap a left end of the second heat generation body 112b of the second heater 110b, and the second connection terminal 114b of the second heater 110b may be disposed to overlap a right end of the first heat generation body 112a of the first heater 110a. As a result, the first connection terminal 114a of the first heater 110a and the second connection terminal 114b of the second heater 110b may be disposed so as not to overlap each other, and the first heat generation body 112a of the first heater 110a and the second heat generation body 112b of the second heater 110b may be disposed so as not to overlap each other. Thus, a certain amount of heat may be released by the first heat generation body 112a and the second heat generation body 112b on the entire area in the X-axis direction, and as a result, the substrate may be uniformly heated.

Although two first heaters 110a are disposed in the Y-axis direction, and two second heaters 110b are disposed in the Y-axis direction at a side of the first heater 110a in the X-axis direction in FIGS. 1 and 2, the number of first heaters 110a and second heaters 110b and an arrangement direction of first heaters 110a and second heaters 110b may be variously changed in accordance with a size of the substrate and a heat generation amount.

The substrate heating part 100 in accordance with an exemplary embodiment may further include an electrode 130 to which an external power source is connected to supply power to the plurality of heaters 110a and 110b and a cover 140 having a through-hole (not shown) and provided on the electrode 130 in addition to the plurality of heaters 110a and 110b.

Here, the substrate heating part 100 may be installed at various positions. For example, the substrate heating part 100 may be installed on a bottom surface of a chamber that provides a process space, or a plate-shaped body having a predetermined thickness may be separately provided to install the substrate heating part 100 on the body.

The electrode 130 may be configured to connect the external power source to the plurality of heaters 110a and 110b. The electrode 130 may be provided, for example, on the bottom surface of the chamber or a top surface of the body. As described above, the electrode 130 may have a shape of a busbar to simultaneously supply power to the plurality of heaters 110a and 110b. For example, the electrode 130 may extend in the Y-axis direction so as to be electrically connected to the first connection terminal 114a of the plurality of first heaters 110a disposed in the Y-axis direction and may extend in the Y-axis direction so as to be electrically connected to the second connection terminal 114b of the plurality of second heaters 110b. However, the shape of the electrode 130 may not be limited thereto and may be variously changed.

The first connection terminal 114a provided on the plurality of first heaters 110a and the second connection terminal 114b provided on the plurality of second heaters 110b may be connected to the above-described electrode 130. Here, the substrate heating part 100 in accordance with an exemplary embodiment may further include the cover 140 made of an insulating material for preventing arcing from occurring between the first connection terminal 114a and the electrode 130. For example, the cover 140 may be made of a ceramic or quartz material.

The cover 140 may be provided on the electrode 130, and the through-hole may be defined in the cover 140 so that the connection terminals 114a and 114b pass through and are connected to the electrode 130. For example, the through-hole may be provided in plurality so that the connection terminals 114a and 114b is connected to the electrode 130 disposed below the cover 140 through the plurality of through-holes, respectively. As illustrated in the drawings, although the cover 140 extends in the Y-axis direction on the electrode 130, the cover 140 may have various shapes such as covering the electrode 130 as a whole.

The substrate heating part 100 in accordance with an exemplary embodiment may further include a connection member 150 that connects the connection terminal to the electrode by passing through the through-hole. For example, the connection member 150 may include a wire having conductivity to easily connect the connection terminals 114a and 114b to the electrode 130 extending downward through the through-hole. That is, the connection terminals 114a and 114b may extend in the X-axis direction from an upper portion of the through-hole or a side portion of the through-hole on the electrode 130, and the electrode 130 may extend in the Y-axis direction from a lower side of the through-hole. Here, the connection terminals 114a and 114b disposed on the electrode 130 and the electrode 130 disposed below the through-hole may be connected to each other through the connection member 150. The connection member 150 may be firmly coupled to the electrode 130 by a bolt inserted into the through-hole.

In addition, the substrate heating part 100 in accordance with an exemplary embodiment may further include a reflection plate 160 provided below the plurality of heaters 110a and 110b. Although FIG. 2 illustrates a state in which the reflection plate 160 is provided below the electrode 130, the reflection plate 160 may be provided above the electrode 130 to expose the electrode 130. Here, all of the plurality of heaters 110a and 110b may be disposed on the reflection plate 160, and an edge of the reflection plate 160 may be bent to surround the plurality of heaters 110a and 110b, thereby inducing heat released from lower sides and side surfaces of the plurality of heaters 110a and 110b toward an upper side of the reflection plate 160. That is, the reflection plate may be bent upward from an edge of a body 12 and may be provided as a metal plate for reflecting the heat released to the lower sides and side surfaces of the plurality of heaters 110a and 110b or made of a metal material such as being coated with a metal.

FIG. 3 is a view illustrating a state in which the substrate heating device is installed in a reaction chamber in accordance with an exemplary embodiment.

Referring to FIG. 3, an apparatus for processing the substrate in accordance with an exemplary embodiment may be an apparatus for depositing a thin film and include a reaction chamber 10 providing a process space for deposition, a substrate heating device provided in the reaction chamber 10 and including a substrate support part 200 and a substrate heating part 100, and a gas injection part provided in the reaction chamber 10 to face the substrate support part 200 and injecting a process gas toward the substrate support part 200. In addition, the apparatus for processing the substrate may further include an RF power source (not shown) applying power to generate plasma in the chamber 10 and a controller (not shown) controlling the RF power source.

The reaction chamber 10 provides a predetermined process space and is maintained to be sealed. The reaction chamber 10 may include a body 12 including an approximately circular or square-shape plane and a sidewall extending upward from the plane and having a predetermined space and a cover 14 having an approximately circular or square shape and disposed on the body 12 to seal the reaction chamber 10. However, the reaction chamber 10 is not limited thereto and may be manufactured in various shapes corresponding to a shape of the substrate S.

The substrate S provided into the chamber 10 may be seated on the substrate support part 200. The substrate support part 200 may include an electrostatic chuck to adsorb and maintain the substrate S by using an electrostatic force so that the substrate S is seated and supported. Alternatively, the substrate support part 200 may support the substrate S through vacuum adsorption or mechanical force.

The substrate support part 200 may be provided in a shape corresponding to a shape of the substrate S, for example, a circular shape or a rectangular shape. The substrate support part 200 may include a substrate support on which the substrate S is seated and an elevator disposed under the substrate support to elevate the substrate support. Here, the substrate support may be manufactured to be larger than the substrate S, and the elevator may be provided to support at least one area of the substrate support, for example, a central portion. When the substrate S is seated on the substrate support, the substrate support may move to approach the gas injection part 20.

The gas injection part 20 may include a gas injector 24 installed inside the chamber 10 and a gas supplier 22 communicating with the gas injector 24 so that at least a portion of the gas supplier 22 extends to the outside of the chamber 10.

The gas supplier 22 supplies a process gas to the gas injector 24, and the gas injector 24 is provided at an upper side the inside of the reaction chamber 10 to inject the process gas toward the substrate S. The gas injector 24 may have a predetermined space. Also, the gas injector 24 may have an upper portion connected to the gas supplier 22 and a lower portion in which a plurality of injection holes (not shown) for injecting the process gas onto the substrate S are defined. The gas injector 24 may have a shape corresponding to that of the substrate S, for example, an approximately circular or square shape. Here, the gas injector 24 may be provided to be spaced a predetermined interval from the sidewall and the cover 14 of the reaction chamber 10. In addition, in the case of depositing the thin film using plasma, the gas injector 24 may act as an upper electrode receiving power from the RF power source.

To deposit the thin film, the substrate has to be heated to a predetermined temperature. Thus, in the apparatus for processing the substrate in accordance with an exemplary embodiment, the substrate heating part 100 is installed below the substrate support part 200, for example, the substrate support. As described above, the substrate heating part 100 may include a plurality of heaters 110a and 110b having ends provided with connection terminals 114a and 114b and extending in one direction from the ends, and the plurality of heaters 110a and 110b may be disposed so that partial areas including the ends overlap each other. In addition, the substrate heating part 100 may further include an electrode 130, to which a power source is connected, and a cover 140 having a through-hole and provided on the electrode 130 and also may further include a reflection plate 160 provided below the plurality of heaters 110a and 110b.

FIG. 4 is a view illustrating a state in which the substrate heating device is installed in a loadlock chamber in accordance with an exemplary embodiment.

Referring to FIG. 4, an apparatus for processing a substrate may be an apparatus for transferring a substrate S to a reaction chamber while repeating a vacuum state and an atmospheric pressure state and may include a loadlock chamber 60 having a process space, in which the substrate S is accommodated and heated, and a substrate heating device provided in the process space of the loadlock chamber 60 and including a substrate support part 200 and a substrate heating part 100.

Although not shown, the loadlock chamber 60 may include a plurality of slots providing respective process spaces. In addition, a plurality of gates may be provided in the loadlock chamber 60. Here, the plurality of gates may be provided to allow a transfer chamber to communicate with the loadlock chamber 60 and open and close the transfer chamber and the loadlock chamber 60. One gate or a plurality of gates may be provided in the loadlock chamber 60. Here, a gate valve (not shown) may be provided in the loadlock chamber 60 to open and close the gate.

In addition, a pumping unit and a venting unit may be provided in the loadlock chamber 60. The pumping unit may serve to create the vacuum state inside the loadlock chamber 60. Here, the pumping unit may be provided as, for example, a vacuum pump. The venting unit may serve to create the atmospheric pressure state inside the loadlock chamber 60. The venting unit may inject a purge gas into the loadlock chamber 60 so that the inside of the loadlock chamber 60 is changed from the vacuum state to the atmospheric pressure state. Here, an inert gas such as nitrogen may be used, for example, as the purge gas. In addition, the purge gas injected from the venting unit may serve to remove foreign substances attached to the substrate S placed on the substrate support.

The substrate S disposed in the loadlock chamber 60 may be preheated to a predetermined temperature for subsequent processing. Thus, in the apparatus for processing the substrate in accordance with an exemplary embodiment, the substrate heating part 100 is installed below the substrate support part 200. As described above, the substrate heating part 100 may include a plurality of heaters 110a and 110b having ends provided with connection terminals 114a and 114b and extending in one direction from the ends, and the plurality of heaters 110a and 110b may be disposed so that partial areas including the ends overlap each other. In addition, the substrate heating part 100 may further include an electrode 130, to which an external power source is connected, and a cover 140 having a through-hole and provided on the electrode 130 and also may further include a reflection plate 160 provided below the plurality of heaters 110a and 110b.

In accordance with the exemplary embodiment, the plurality of heaters may be disposed so that the partial areas of the connection terminals overlap each other to minimize the non-heat generation area on which the heat is not generated, thereby uniformly heating the substrate.

In addition, the insulating cover may be disposed between the connection terminal provided in each heater and the electrode for applying the power to the connection terminal to prevent the arc from being generated, and the heat released from the heater may be concentrated into the substrate through the reflection plate to improve the heating efficiency.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A substrate heating device comprising:
a substrate support part configured to seat a substrate thereon; and
a plurality of heaters which is provided below the substrate support part and each of which comprises a connection terminal provided on an end of each of the plurality of heaters and a heat generation body extending from the connection terminal in one direction,
wherein the plurality of heaters are disposed alternatively so that partial areas comprising the ends overlap each other in another direction crossing the direction.

2. The substrate heating device of claim 1, wherein the plurality of heaters comprise a first heater and a second heater, which are disposed alternatively,
wherein the first heater and the second heater are disposed so that the connection terminals do not overlap each other, and the heat generation bodies do not overlap each other.

3. The substrate heating device of claim 1, further comprising:
an electrode to which a power source is connected; and
a cover having a through-hole and provided on the electrode,
wherein the connection terminal is electrically connected to the electrode through the through-hole.

4. The substrate heating device of claim 3, further comprising a connection member passing through the through-hole to connect the connection terminal to the electrode.

5. The substrate heating device of claim 4, further comprising a bolt inserted into the through-hole so that the connection member is coupled to the electrode.

6. The substrate heating device of claim 3, wherein the cover is made of an insulating material.

7. The substrate heating device of claim 1, further comprising a reflection plate provided below the plurality of heaters.

8. The substrate heating device of claim 7, wherein all of the plurality of heaters are disposed on the reflection plate, and
an edge of the reflection plate is bent to surround the plurality of heaters.

9. An apparatus for processing a substrate, comprising:
a chamber configured to provide a process space; and
the substrate heating device, which is installed in the process space, of claim 1.
